(19) United States
(12) Patent Application Publication
(10) Pub. No.: US 2026/0214935 A1
(43) Pub. Date: Jul. 23, 2026

(54) INSULATED GATE SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 19/404,677

(22) Filed: Dec. 1, 2025

(30) Foreign Application Priority Data
Jan. 17, 2025 (JP) 2025-006542

(51) Int. Cl. H10D 30/66; H10D 62/10; H10D 62/832; H10D 64/00

(52) U.S. Cl. CPC H10D 30/665; H10D 30/668; H10D 62/107; H10D 62/109; H10D 62/8325; H10D 64/111

(57) ABSTRACT

An insulated gate semiconductor device includes: a drift layer of a first conductivity-type provided along an active part including an active element and an edge termination part surrounding a circumference of the active part; and a plurality of fin parts of the first conductivity-type provided separately from each other on a top surface side of the drift layer in the edge termination part so as to surround the circumference of the active part.

### CROSS-REFERENCE TO RELATED APPLICATION

This application claims benefit of priority under 35 USC 119 based on Japanese Patent Application No. 2025-006542 filed on January 17, 2025, the entire contents of which are incorporated by reference herein.

### BACKGROUND OF THE INVENTION

### 1. Field of the Invention

The present disclosure relates to insulated gate semiconductor devices.

### 2. Description of the Related Art

JP6631632B2 (Patent Literature 1) and F, Udrea et al., “Experimental demonstration, challenges, and prospects of the vertical SiC FinFET”, 2022 IEEE 34th ISPSD, May 2022 (Non-Patent Literature 1), each disclose a vertical SiC-MOSFET having a trench-gate structure provided with unit cells with a FinFET structure.

The configurations of edge termination parts in the semiconductor devices as disclosed in Patent Literature 1 and Non-Patent Literature 1 are still required to be improved in order to relax an electric field and improve breakdown voltage.

### SUMMARY OF THE INVENTION

The present disclosure provides an insulated gate semiconductor device having a configuration capable of relaxing an electric field at an edge termination part and improving breakdown voltage.

To solve the problems described above, an aspect of the present disclosure inheres in an insulated gate semiconductor device including: a drift layer of a first conductivity-type provided along an active part including an active element and an edge termination part surrounding a circumference of the active part; and a plurality of fin parts of the first conductivity-type provided separately from each other on a top surface side of the drift layer in the edge termination part so as to surround the circumference of the active part.

The active element may include: a base region of a second conductivity-type provided on the top surface side of the drift layer; main region of the first conductivity-type provided on a top surface side of the base region; and a gate electrode buried, with a gate insulating film interposed, in a pair of first trenches interposing side surfaces of the base region and the main region, and an inversion layer may be formed in a region separated from an interface between the base region and the gate insulating film.

A width of the base region may be 0.2 micrometers or less.

A width of the respective fin parts may be gradually increased toward an outer side of the edge termination part.

A width of the respective fin parts may be uniform from an inner side to an outer side of the edge termination part.

A width of the respective fin parts on an innermost side of the edge termination part may be 0.2 micrometers or smaller.

A second trench may be provided between the fin parts adjacent to each other.

A depth of the second trench may be common to a depth of the first trenches.

The insulated gate semiconductor device may further include a guard ring layer of the second conductivity-type provided on the top surface side of the drift layer immediately under the second trench.

The guard ring layer may be in contact with a bottom surface of the second trench.

The guard ring layer may be separated from a bottom surface of the second trench.

The gate insulating film may be provided on a side surface of the second trench.

A polysilicon layer may be provided on the side surface of the second trench with the gate insulating film interposed.

A polysilicon layer may be provided on a side surface of the second trench.

The insulated gate semiconductor device may further include a field plate provided on a top surface side of the respective fin parts with an insulating film interposed.

It should be noted that the above summary of the invention does not list all the necessary features of the present invention. Subcombinations of these feature groups can also be inventions.

### BRIEF DESCRIPTION OF THE DRAWINGS

FIG. 1 is a plan view illustrating an insulated gate semiconductor device according to a first embodiment;

FIG. 2 is a cross-sectional view illustrating the insulated gate semiconductor device according to the first embodiment;

FIG. 3 is a cross-sectional view taken along line A-A in FIG. 2;

FIG. 4 is a cross-sectional view taken along line B-B in FIG. 3;

FIG. 5 is a cross-sectional view illustrating the insulated gate semiconductor device according to the first embodiment;

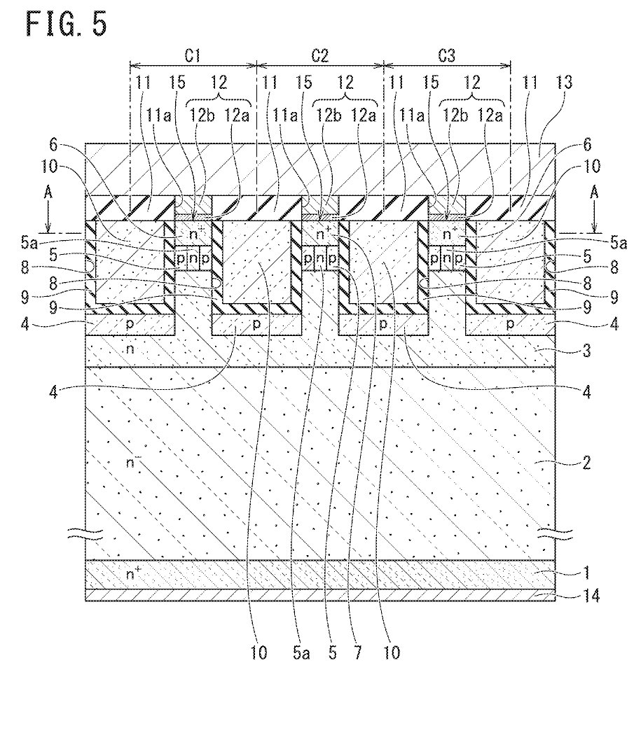

FIG. 6 is a cross-sectional view illustrating the insulated gate semiconductor device according to the first embodiment;

FIG. 7 is a cross-sectional view illustrating an insulated gate semiconductor device according to a second embodiment;

FIG. 8 is a cross-sectional view illustrating an insulated gate semiconductor device according to a third embodiment;

FIG. 9 is a cross-sectional view illustrating an insulated gate semiconductor device according to a fourth embodiment;

FIG. 10 is a cross-sectional view illustrating an insulated gate semiconductor device according to a fifth embodiment;

FIG. 11 is a cross-sectional view illustrating an insulated gate semiconductor device according to a sixth embodiment;

FIG. 12 is a cross-sectional view illustrating an insulated gate semiconductor device according to a seventh embodiment;

FIG. 13 is a cross-sectional view illustrating an insulated gate semiconductor device according to an eighth embodiment; and

FIG. 14 is a cross-sectional view illustrating an insulated gate semiconductor device according to a ninth embodiment.

### DETAILED DESCRIPTION

With reference to the drawings, first to ninth embodiments of the present disclosure will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description.

Moreover, in some drawings, portions are illustrated with different dimensional relationships and proportions.

The first to ninth embodiments described below merely illustrates schematically devices and methods for specifying and giving shapes to the technical idea of the present disclosure, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOSFET transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “-” indicates that such semiconductor region has a relatively low impurity concentration or a relatively high specific resistance as compared to a semiconductor region denoted by the symbol “n” or “p” without “-”. However, even when the semiconductor regions are denoted by the same reference symbols “n” and “n”, it is not indicated that the semiconductor regions have exactly the same impurity concentration or the same specific resistance.

Further, the term “substantially the same” or “substantially common” regarding impurity concentrations, widths, depths, thicknesses, or the like as used herein encompasses the meanings corresponding to not only strictly the same range but also a range including a margin of error derived from variations in process. The margin of error is plus or minus 10% of a corresponding value, for example.

### FIRST EMBODIMENT

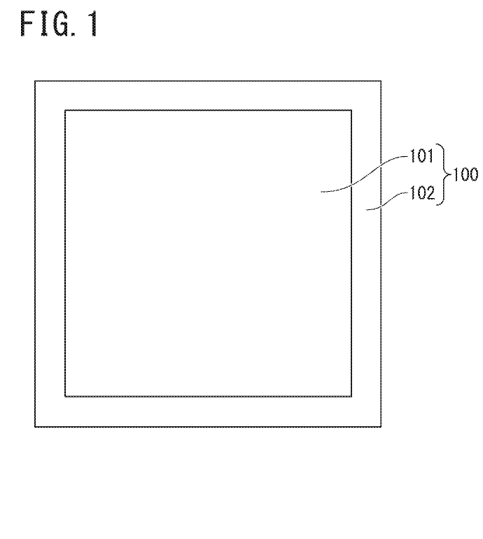

An insulated gate semiconductor device according to a first embodiment includes a semiconductor chip 100, as illustrated in FIG. 1. The first embodiment illustrates a case in which the semiconductor chip 100 includes silicon carbide (SiC). The semiconductor chip 100 has a substantially rectangular planar shape. The semiconductor chip 100 includes an active part 101, and an edge termination part (a voltage blocking structure) 102 provided along a circumference of the active part 101.

The active part 101 is located substantially in the middle of the semiconductor chip 100, and has a substantially rectangular planar shape. The active part 101 includes an active element which is a power switching element, and serves as a region through which a main current (a drift current) flows when the active element is in an ON state.

The edge termination part 102 has a loop-like (frame-like) planar shape surrounding the circumference of the active part 101. The edge termination part 102 serves as a region that relaxes an electric field on the top surface side of the semiconductor chip 100 to keep a breakdown voltage. The term “breakdown voltage” refers to an upper-limit voltage that can prevent the insulated gate semiconductor device according to the first embodiment from causing wrong operations or damage with a voltage in use.

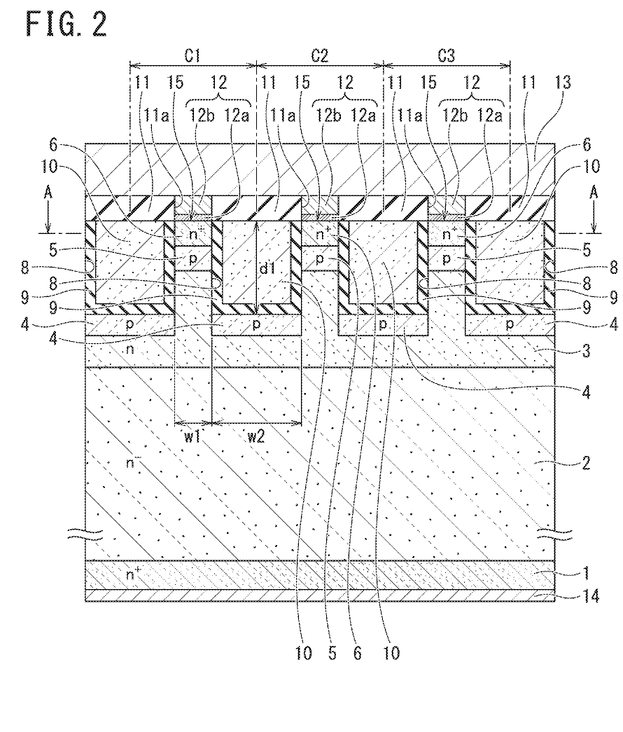

FIG. 2 is a vertical cross-sectional view illustrating the active part 101 illustrated in FIG. 1. As illustrated in FIG. 2, the insulated gate semiconductor device according to the first embodiment is illustrated with a case in which the active element in the active part 101 is a vertical MOSFET (SiC-MOSFET) having a trench-gate structure. The insulated gate semiconductor device according to the first embodiment includes unit cells C1 to C3 which are each a function unit of the active element. The unit cells C1 to C3 are aligned in the right-left direction in FIG. 2. While FIG. 2 illustrates the case of including the three unit cells C1 to C3, the present embodiment may be applied to a case in which more than three cells are arranged in a similar manner so as to have a multiple-channel structure.

The insulated gate semiconductor device according to the first embodiment includes a drift layer 2 which is a semiconductor region of a first conductivity-type (n⁻-type) in the active part 101. The drift layer 2 is an epitaxial growth layer including silicon carbide (SiC), for example. An impurity concentration and a thickness of the drift layer 2 can be regulated as appropriate depending on specifications of breakdown voltage and the like. The impurity concentration of the drift layer 2 is set in a range of about 1 × 10¹⁵ cm⁻³ or higher and 5 × 10¹⁶ cm⁻³ or lower, for example.

A current spreading layer (CSL) 3 which is a semiconductor region of the first conductivity-type (n-type) having a higher impurity concentration than the drift layer 2 is provided on the top surface side of the drift layer 2. The current spreading layer 3 is an epitaxial growth layer including SiC, for example. The current spreading layer 3 has an impurity concentration set in a range of about 5 × 10¹⁶ cm⁻³ or higher and 5 × 10¹⁷ cm⁻³ or lower, for example. The provision of the current spreading layer 3 is optional.

A base region 5 which is a semiconductor region of a second conductivity-type (p-type) is provided on the top surface side of the current spreading layer 3 in the respective unit cells C1 to C3. The base region 5 is an epitaxial growth layer including SiC, for example. The base region 5 has an impurity concentration set in a range of about 1 × 10¹⁷ cm⁻³ or higher and 1 × 10¹⁸ cm⁻³ or lower, for example. The bottom surface of the base region 5 may be in contact with the top surface of the drift layer 2 when the current spreading layer 3 is not provided.

A first main region (a source region) 6 which is a semiconductor region of the first conductivity-type (n⁺-type) having a higher impurity concentration than the drift layer 2 is provided on the top surface side of the base region 5 in the respective unit cells C1 to C3. The source region 6 is an epitaxial growth layer including SiC, for example. The source region 6 has an impurity concentration set in a range of about 1 × 10¹⁷ cm⁻³ or higher and 5 × 10¹⁸ cm⁻³ or lower, for example.

A plurality of trenches 8 (also referred to below as “active-side trenches”) are dug downward from the top surface of the source region 6 so as to penetrate the source region 6 and the base region 5 in a direction normal to the top surface of the source region 6 (in a depth direction). The bottom surfaces of the active-side trenches 8 reach the current spreading layer 3. The side surfaces of the active-side trenches 8 are in contact with the source region 6, the base region 5, and the current spreading layer 3. When the current spreading layer 3 is not provided, the bottom surfaces of the active-side trenches 8 reach the drift layer 2, and the side surfaces of the active-side trenches 8 are in contact with the source region 6, the base region 5, and the drift layer 2.

A width w2 of the respective active-side trenches 8 is set in a range of about 0.3 micrometers or greater and 1.0 micrometers or smaller, for example. A depth d1 of the respective active-side trenches 8 is set in a range of about 0.7 micrometers or greater and 1.3 micrometers or smaller, and may be 1 micrometer, for example. While FIG. 2 illustrates the case in which the side surfaces of the active-side trenches 8 are vertical flat surfaces, the respective side surfaces of the active-side trenches 8 can have a tapered shape of either a trapezoid or an inverted trapezoid in cross section, or can be a curved surface convex outward. In addition, FIG. 2 illustrates the case in which the bottom surfaces of the active-side trenches 8 are flat surfaces, but the respective bottom surfaces of the active-side trenches 8 can be a curved surface convex downward. Further, an angle between the bottom surface and the side surface of the respective active-side trenches 8 can have a curvature.

The unit cells C1 to C3 have active-side fin parts 15, each serving as a mesa part which is a semiconductor region, interposed between the active-side trenches 8 adjacent to each other. The respective active-side fin parts 15 include part of the source region 6, the base region 5, and the current spreading layer 3 interposed between the active-side trenches 8 adjacent to each other. When the current spreading layer 3 is not provided, the respective active-side fin parts 15 include part of the source region 6, the base region 5, and the drift layer 2 interposed between the active-side trenches 8 adjacent to each other.

A width w1 of the respective active-side fin parts 15 conforms to a width of a part of each of the source region 6, the base region 5, and the current spreading layer 3 interposed between the active-side trenches 8 adjacent to each other. The width w1 of the respective active-side fin parts 15 is narrower than the width w2 of the respective active-side trenches 8. The width w1 of the respective active-side fin parts 15 is set in a range of about 50 nanometers or greater and 0.2 micrometers or smaller, for example. The width w1 of the respective active-side fin parts 15 may be in a range of about 0.1 micrometers or greater and 0.2 micrometers or smaller, or may be in a range of about 50 nanometers or greater and 0.1 micrometer or smaller. Setting the width w1 of the respective active-side fin parts 15 to about 0.2 micrometers or smaller can achieve a FinFET structure as described below.

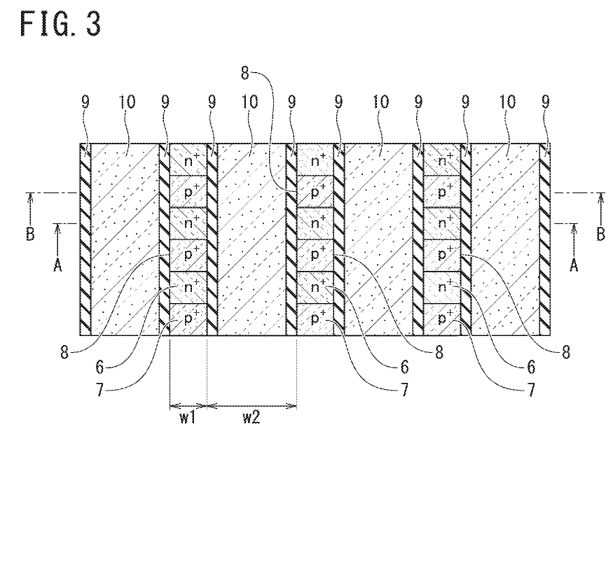

FIG. 3 is a horizontal cross-sectional view taken along line A-A in FIG. 2 as viewed from the top surface side. The vertical cross section taken along line A-A in FIG. 3 as viewed from the lower side to the upper side corresponds to the cross section of FIG. 2. As illustrated in FIG. 3, the active-side trenches 8, a gate insulating film 9, and a gate electrode 10 each have a planar pattern extending straight (in a stripe state) parallel to each other in one direction (in the upper-lower direction in FIG. 3). The source region 6 and a base contact region 7 which is a semiconductor region of the second conductivity-type (p⁺-type) are alternately and repeatedly arranged in one direction (in the upper-lower direction in FIG. 3) between the respective active-side trenches 8. The source region 6 and the base contact region 7 are in contact with each other.

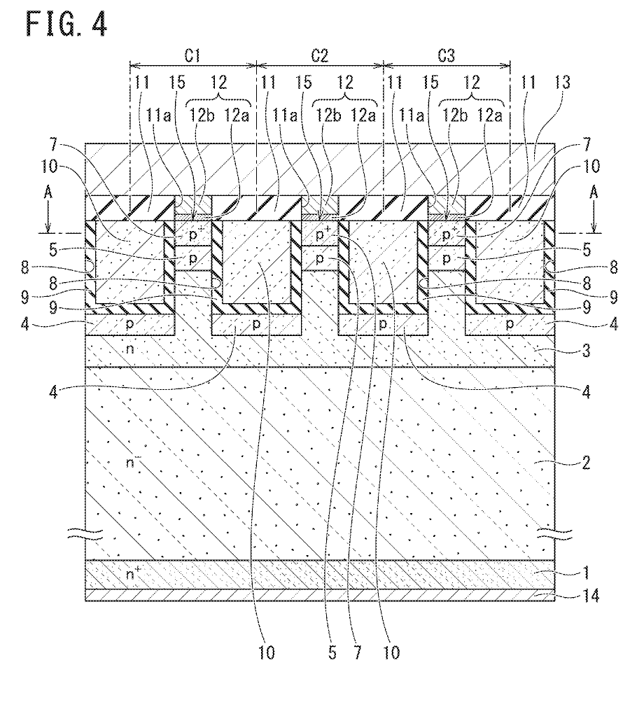

FIG. 4 is a vertical cross-sectional view taken along line B-B in FIG. 3 as viewed from the lower side to the upper side in FIG. 3. As illustrated in FIG. 4, the base contact region 7 is provided on the top surface side of the base region 5 in the respective unit cells C1 to C3. A depth of the base contact region 7 may be the same as that of the source region 6 illustrated in FIG. 2, or may be either deeper or shallower than that of the source region 6. The bottom surface of the base contact region 7 is in contact with the top surface of the base region 5. The side surfaces of the base contact region 7 are in contact with the respective active-side trenches 8. The base contact region 7 is an epitaxial growth layer including SiC, for example. The base contact region 7 has a higher impurity concentration than the base region 5. The impurity concentration of the base contact region 7 is set in a range of about 5 × 10¹⁹ cm⁻³ or higher and 5 × 10²⁰ cm⁻³ or lower, for example. The respective active-side fin parts 15 in cross section shown in FIG. 4 include the base contact region 7, the base region 5, and a part of the current spreading layer 3 interposed between the active-side trenches 8 adjacent to each other.

The gate insulating film 9 is provided along the bottom and side surfaces of the respective active-side trenches 8. The gate electrode 10 is buried inside the respective active-side trenches 8 with the gate insulating film 9 interposed. The gate insulating film 9 and the gate electrode 10 implement a trench-gate type insulated gate electrode structure (9, 10).

A thickness of the gate insulating film 9 is set in a range of about 30 nanometers or greater and 100 nanometers or smaller, for example. The gate insulating film 9 may be a single-layer film of a silicon oxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or may be a composite film including some of the above films stacked on one another. The gate electrode 10 may be implemented by a polysilicon layer (a doped polysilicon layer) heavily doped with p-type impurities or n-type impurities, or may include refractory metal, such as titanium (Ti), tungsten (W), and nickel (Ni).

An insulating film 11 which is an interlayer insulating film is provided on the top surface side of the gate electrode 10. The insulating film 11 as used herein can be a silicon oxide film (a SiO₂ film) without containing impurities, which is referred to as a non-doped silicate glass (NSG) film, a phosphosilicate glass film (a PSG film), a borosilicate glass film (a BSG film), a borophosphosilicate glass film (a BPSG film), or a silicon nitride film (a Si₃N₄ film), or can be a composite film including some of the above films combined together.

As illustrated in FIGS. 2 and FIG.4, the insulating film 11 is provided with openings (contact holes) 11a on which the respective top surfaces of the source region 6 and the base contact region 7 are at least partly exposed. A contact electrode 12 is buried inside the respective contact holes 11a. The contact electrode 12 is in ohmic contact with the source region 6 and the base contact region 7 at low resistance.

The contact electrode 12 includes a barrier metal layer 12a directly in contact with the respective top surfaces of the source region 6 and the base contact region 7, and a plug layer 12b with the bottom surface in contact with the top surface of the barrier metal layer 12a. The barrier metal layer 12a includes metal such as titanium nitride (TiN) and titanium (Ti), or metal having a stacked structure of TiN/Ti including Ti as a lower layer. The barrier metal layer 12a may be provided to cover the insulating film 11. A silicide layer including nickel silicide (NiSiₓ) for ohmic contact may be provided between the barrier metal layer 12a and each of the source region 6 and the base contact region 7. The plug layer 12b includes metal such as tungsten (W).

A first main electrode (a source electrode) 13 is provided to cover the respective top surfaces of the insulating film 11 and the contact electrode 12. The source electrode 13 is provided separately from a gate wiring layer (not illustrated) electrically connected to the gate electrode 10. The source electrode 13 includes metal such as aluminum (Al) and copper (Cu) or a metal alloy such as aluminum-silicon (Al-Si) and aluminum-copper (Al-Cu).

As illustrated in FIG. 2, a gate-bottom protection region 4 which is a semiconductor region of the second conductivity-type (p⁺-type) is provided inside the current spreading layer 3. The gate-bottom protection region 4 has a function capable of relaxing the electric field applied to the gate insulating film 9 provided on the bottom surface of the respective active-side trenches 8. The gate-bottom protection region 4 has an impurity concentration set in a range of about 1 × 10¹⁷ cm⁻³ or higher and 1 × 10¹⁹ cm⁻³ or lower, for example. The gate-bottom protection region 4 is electrically connected to the base region 5 on the frontward side or backward side of the sheet of FIG. 2.

While FIG. 2 illustrates the case in which the gate-bottom protection region 4 is in contact with the respective bottom surfaces of the active-side trenches 8, the gate-bottom protection region 4 may be separated from the bottom surfaces of the active-side trenches 8. Further, FIG. 2 illustrates the case in which the gate-bottom protection region 4 has a width common to the width w2 of the respective active-side trenches 8, but the width of the gate-bottom protection region 4 may be either smaller or greater than the width w2 of the active-side trenches 8. When the current spreading layer 3 is not provided, the gate-bottom protection region 4 may be provided inside the drift layer 2. The provision of the gate-bottom protection region 4 is optional in the present embodiment.

A second main region (a drain region) 1 which is a semiconductor region of the first conductivity-type (n⁺-type) having a higher impurity concentration than the drift layer 2 is provided on the bottom surface side of the drift layer 2. The drain region 1 is a semiconductor substrate (a SiC substrate) including SiC, for example. The drain region 1 has an impurity concentration set in a range of about 1 × 10¹⁹ cm⁻³ or higher and 3 × 10²⁰ cm⁻³ or lower, for example. Any of a buffer layer, a dislocation conversion layer, or a recombination promotion layer, which is a semiconductor region of n-type having a higher impurity concentration than the drift layer 2 and having a lower impurity concentration than the drain region 1, may be provided between the drift layer 2 and the drain region 1.

A second main electrode (a drain electrode) 14 is provided on the bottom surface side of the drain region 1. The drain electrode 14 may be a single-layer film including gold (Au) or a metal-stacked film including titanium (Ti), nickel (Ni), and Au sequentially stacked together from the drain region 1 side, and may further include a metal film including molybdenum (Mo) and tungsten (W) on the lowermost layer. A silicide layer including nickel silicide (NiSiₓ) may be provided for ohmic contact between the drain region 1 and the drain electrode 14.

The insulated gate semiconductor device according to the first embodiment during the switching operation applies a positive voltage to the drain electrode 14 with the source electrode 13 used as an earth potential, and also applies a positive voltage of a threshold or greater to the gate electrode 10. This operation provides inversion layers (channels) in the base region 5 in the respective unit cells C1 to C3 so as to lead the vertical MOSFET to be in an ON-state. In the ON-state, a current flows from the drain electrode 14 toward the source electrode 13 through the drain region 1, the drift layer 2, the inversion layers in the base region 5, and the source region 6. When the voltage applied to the gate electrode 10 is less than the threshold, the vertical MOSFET is led to be in an OFF-state while no current flows from the drain electrode 14 toward the source electrode 13, since no inversion layers are formed in the base region 5.

In the insulated gate semiconductor device according to the first embodiment, the vertical MOSFET implements a FinFET structure. The FinFET structure is configured to set the width w1 of the respective active-side fin parts 15 interposed between the active-side trenches 8 adjacent to each other to a predetermined small value so as to form the inversion layers (channels) in the base region 5 interposed between the active-side trenches 8 adjacent to each other. This structure is typically referred to as a double-gate structure. When a gate voltage of a threshold or greater is applied to the gate electrode 10, the FinFET structure leads the voltage between the paired (two) gate electrodes 10 interposing the base region 5 to be applied to the entire base region 5. When the width w1 of the respective active-side fin parts 15 is set in the range of about 0.1 micrometers or greater and 0.2 micrometers or smaller, a single inversion layer 5a is formed not adjacent to the interface between the base region 5 and the respective gate insulating films 9 on the right and left sides but in a region (a bulk region) separated from the interface with the respective gate insulating films 9 on the right and left side. The inversion layer 5a is formed in the region separated from the interface between the base region 5 and the respective gate insulating films 9 on the right and left sides by a distance in a range of about 0.05 micrometers or greater and 0.1 micrometers or smaller, for example. The inversion layer 5a is located in the middle of the base region 5 in the horizontal direction.

The configuration of the insulated gate semiconductor device according to the first embodiment as described above thus can prevent electrons moving inside the inversion layer 5a from being influenced by interface trap density at the interface between the base region 5 and the respective gate insulating films 9 more effectively than a case in which the inversion layer is formed adjacent to the interface between the base region 5 and the respective gate insulating film 9. This configuration can enhance mobility of electrons and can suppress the ON-resistance accordingly.

The interface trap density is particularly higher in SiC, which is a compound, than in Si by about one digit. The mobility of electrons is influenced by the interface trap density more easily in an insulated gate semiconductor device using SiC than in an insulated gate semiconductor device using Si. The use of the FinFET structure in which the width w1 of the respective active-side fin parts 15 is set in the range of about 0.1 micrometers or greater and 0.2 micrometers or smaller, is thus particularly effective in the insulated gate semiconductor device using SiC.

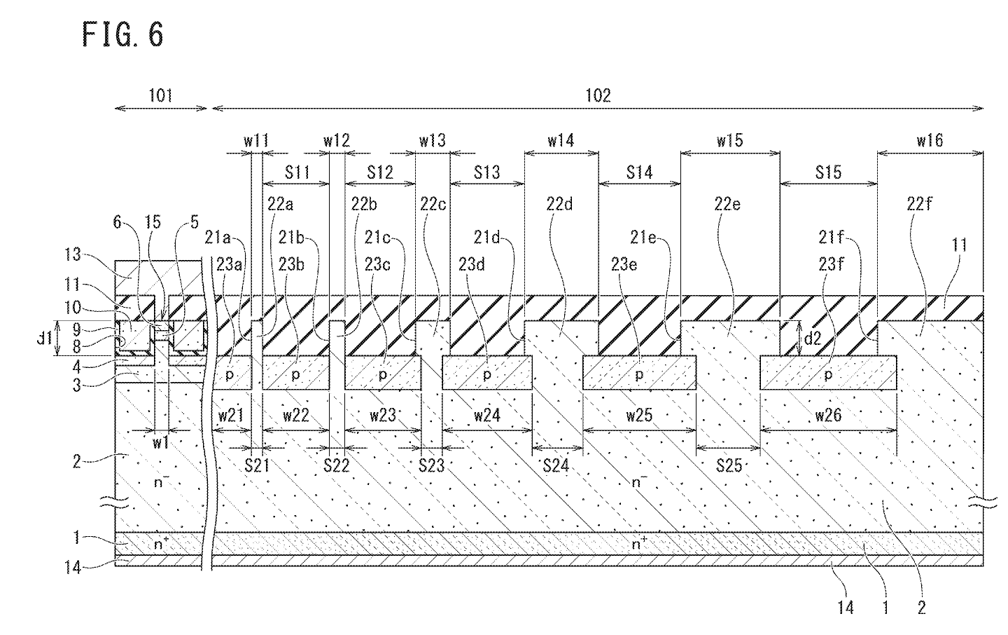

FIG. 6 is a cross-sectional view illustrating the active part 101 and the edge termination part 102. The cross section of the edge termination part 102 corresponds to a region between the inner side toward the active part 101 and the outer side that is the end part of the semiconductor chip 100. The left side of FIG. 6 is the inner side of the edge termination part 102, and the right side of FIG. 6 is the outer side of the edge termination part 102. As illustrated in FIG. 6, the insulated gate semiconductor device according to the first embodiment includes the drift layer 2 of the first conductivity-type (n⁻-type) in the edge termination part 102. The drain region 1 of the first conductivity-type (n⁺-type) is provided on the bottom surface side of the drift layer 2. The drain electrode 14 is provided on the bottom surface side of the drain region 1. The drift layer 2, the drain region 1, and the drain electrode 14 are each continuously provided along the active part 101 and the edge termination part 102.

The FinFET structure applied to the active part 101 is also applied to the edge termination part 102 in the insulated gate semiconductor device according to the first embodiment. In particular, the edge termination part 102 is provided with fin parts (also referred to below as “terminal-side fin parts”) 22a to 22f which are semiconductor regions of the first conductivity-type (n⁻-type) on the top surface side of the drift layer 2. The terminal-side fin parts 22a to 22f have a loop-shaped (frame-shaped) planar pattern surrounding the circumference of the active part 101. While FIG. 6 illustrates the case of including the six terminal-side fin parts 22a to 22f, the number of the terminal-side fin parts may be changed as appropriate. The total number of the terminal-side fin parts, corresponding to the terminal-side fin parts 22ato 22f, may be five or smaller or seven or greater instead.

The terminal-side fin parts 22a to 22f are arranged separately from each other in a concentric state. The terminal-side fin parts 22a to 22f respectively have widths w11 to w16 which are gradually increased from the inner side to the outer side of the edge termination part 102. The widths w11 to w16 of the terminal-side fin parts 22a to 22f may be increased from the inner side to the outer side of the edge termination part 102 by a constant value such as 0.2 micrometers, for example. The width w11 of the terminal-side fin part 22a on the innermost side may be substantially the same as the width w1 of the active-side fin part 15, or may be either narrower than or greater than the width w1 of the active-side fin part 15. The width w11 of the terminal-side fin part 22a on the innermost side is set in a range of about 0.1 micrometers or greater and 0.2 micrometers or smaller, for example. The width w16 of the terminal-side fin part 22f on the outermost side is set in a range of about 0.8 micrometers or greater and 1.2 micrometers or smaller, for example. The widths w11 to w16 of the terminal-side fin parts 22a to 22f may be either uniform or gradually decreased from the inner side to the outer side of the edge termination part 102 instead.

Gaps s11 to s15 between the terminal-side fin parts 22a to 22f are gradually increased from the inner side to the outer side of the edge termination part 102. The gaps s11 to s15 between the terminal-side fin parts 22a to 22f may be either uniform or gradually decreased from the inner side to the outer side of the edge termination part 102 instead.

The terminal-side fin parts 22a to 22f are each an epitaxial growth layer including SiC, for example. The terminal-side fin parts 22a to 22f may be integrated with the drift layer 2. The respective terminal-side fin parts 22a to 22f may have the substantially the same impurity concentration as the drift layer 2. The terminal-side fin parts 22a to 22f can be formed such that he upper part of the drift layer 2 is partly and selectively removed by photolithography and dry etching, for example, after the epitaxial growth of the drift layer 2.

Trenches (also referred to below as “terminal-side trenches”) 21a to 21fare provided between the terminal-side fin parts 22a to 22f adjacent to each other. The respective widths of the terminal-side trenches 21ato 21f conform to the gaps s11 to s15 between the terminal-side fin parts 22a to 22f. A depth d2 of the terminal-side trenches 21ato 21fconforms to a height of the terminal-side fin parts 22bto 22f. The depth d2 of the terminal-side trenches 21a to 21f is substantially the same as the depth d1 of the active-side trenches 8 in the active part 101. The terminal-side trenches 21ato 21f can be formed simultaneously with the active-side trenches 8 in the active part 101 in the same process.

A plurality of guard ring layers 23a to 23f which are semiconductor regions of the second conductivity-type (p⁺-type) are provided on the top surface side of the drift layer 2. The respective guard ring layers 23a to 23f have a loop-shaped (frame-shaped) planar pattern surrounding the circumference of the active part 101. The guard ring layers 23a to 23f are arranged separately from each other in a concentric state with the drift layer 2 interposed. While FIG. 6 illustrates the case of including the six guard ring layers 23a to 23f, the number of the guard ring layers may be changed as appropriate. The total number of the guard ring layers, corresponding to the guard ring layers 23a to 23f, may be five or smaller or seven or greater, for example. The potential of the guard ring layers 23a to 23f may be a floating potential.

The guard ring layers 23a to 23f respectively have widths w21 to w26 which are gradually increased from the inner side to the outer side of the edge termination part 102. The widths w21 to w26 of the guard ring layers 23a to 23f may be either uniform or gradually decreased from the inner side to the outer side of the edge termination part 102. Gaps s21 to s25 between the guard ring layers 23a to 23f are gradually increased from the inner side to the outer side of the edge termination part 102. The gaps s21 to s25 between the guard ring layers 23a to 23f may be either uniform or gradually decreased from the inner side to the outer side of the edge termination part 102 instead.

The guard ring layers 23a to 23f can be formed simultaneously with the base region 5 in the active part 101 in the same process. The guard ring layers 23a to 23f then can have substantially the same impurity concentration as the base region 5 in the active part 101. The guard ring layers 23a to 23f can also be formed simultaneously with the gate-bottom protection region 4 in the active part 101 in the same process. The guard ring layers 23a to 23f then can have substantially the same impurity concentration as the gate-bottom protection region 4 in the active part 101.

The respective guard ring layers 23a to 23f may have an impurity concentration substantially common to each other. The impurity concentration of the respective guard ring layers 23a to 23f may be different from each other. The impurity concentration of the respective guard ring layers 23a to 23f may be gradually decreased from the inner side to the outer side of the edge termination part 102, for example.

The respective guard ring layers 23a to 23f are located immediately under the terminal-side trenches 21a to 21f. The top surfaces of the guard ring layers 23a to 23f are respectively in contact with the bottom surfaces of the terminal-side trenches 21a to 21f. The terminal-side fin parts 22a to 22f are located on the top surface side of the drift layer 2 interposed between the respective guard ring layers 23a to 23f.

A depth from the top surface to the bottom surface of the respective guard ring layers 23a to 23f is substantially common to each other. The depth from the top surface to the bottom surface of the respective guard ring layers 23a to 23f can be different from each other, and may be gradually decreased from the inner side to the outer side of the edge termination part 102, for example.

Although not illustrated in FIG. 6, a channel stopper which is a semiconductor region of the first conductivity-type (n⁺-type) may be arranged to have a loop-shaped (frame-shaped) planar pattern on the top surface side of the drift layer 2 at the end part on the outer side of the edge termination part 102. The channel stopper may be a semiconductor region of the second conductivity-type (p⁺-type) instead.

The insulating film 11 is provided to cover the top surfaces of the guard ring layers 23a to 23f and the side and top surfaces of the terminal-side fin parts 22a to 22f. A field insulating film (not illustrated) such as a film of local oxidation of silicon (LOCOS) or a gate insulating film (not illustrated) may be provided under the insulating film 11 in the edge termination part 102.

The configuration of the insulated gate semiconductor device according to the first embodiment, in which the active element in the active part 101 has the FinFET structure as described above, forms the inversion layer 5a in the region separated from the interface between the respective gate insulating films 9 and the base region 5. This configuration can enhance the mobility of electrons and thus can suppress the ON-resistance more effectively than a case in which the inversion layer is formed adjacent to the interface between the base region 5 and the respective gate insulating films 9.

Further, the insulated gate semiconductor device according to the first embodiment has the configuration in which the FinFET structure applied to the active part 101 is also applied to the edge termination part 102 so as to include the terminal-side fin parts 22a to 22f on the top surface side of the drift layer 2 in the edge termination part 102. This configuration can relax the electric field to improve the breakdown voltage, as compared with a case in which no terminal-side fin parts are provided on the top surface side of the drift layer 2, and thus can decrease the width from the inner side to the outer side of the edge termination part 102.

Further, the configuration according to the present embodiment enables the fabrication of the terminal-side fin parts 22a to 22f simultaneously with the active-side fin parts 15 in the same process, so as to decrease the number of the forming processes required and thus contribute to reducing costs.

Further, the provision of the guard ring layers 23a to 23f immediately under the terminal-side trenches 21a to 21f can further relax the electric field, so as to ensure a stable breakdown voltage.

### SECOND EMBODIMENT

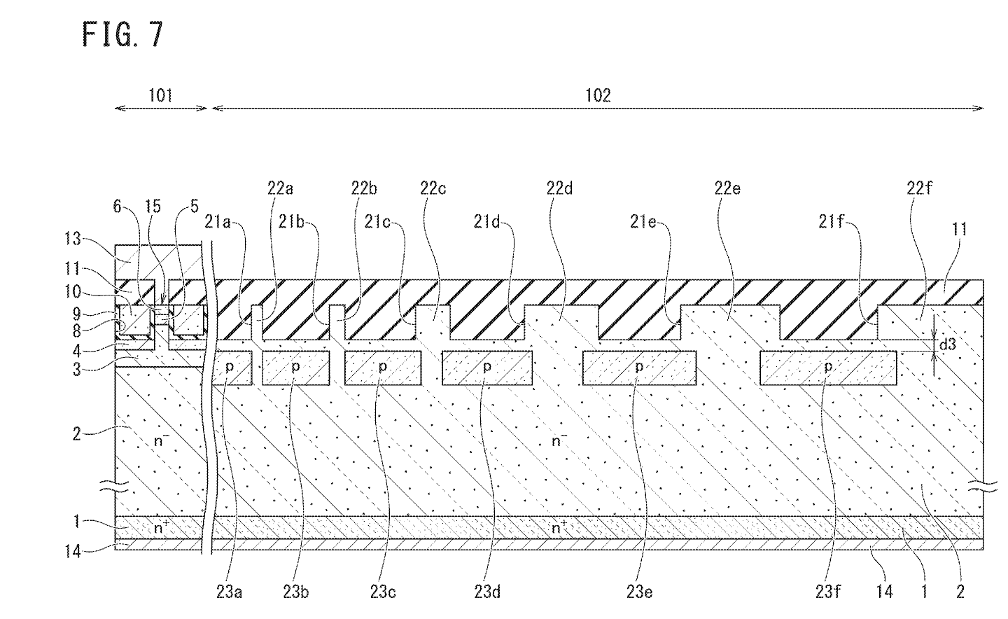

An insulated gate semiconductor device according to a second embodiment differs from the insulated gate semiconductor device according to the first embodiment illustrated in FIG. 6 in that the p-type guard ring layers 23a to 23f in the edge termination part 102 are not in contact with the bottom surfaces of the terminal-side trenches 21a to 21f but separated from each other with the drift layer 2 partly interposed, as illustrated in FIG. 7.

A distance d3 between the respective top surfaces of the guard ring layers 23a to 23f and the respective bottom surfaces of the terminal-side trenches 21a to 21f can be determined as appropriate. The other configurations of the insulated gate semiconductor device according to the second embodiment are substantially the same as those of the insulated gate semiconductor device according to the first embodiment, and overlapping explanations are not repeated below.

The configuration of the insulated gate semiconductor device according to the second embodiment, which includes the terminal-side fin parts 22a to 22f on the top surface side of the drift layer 2 in the edge termination part 102, can relax the electric field to improve the breakdown voltage, as in the case of the insulated gate semiconductor device according to the first embodiment.

### THIRD EMBODIMENT

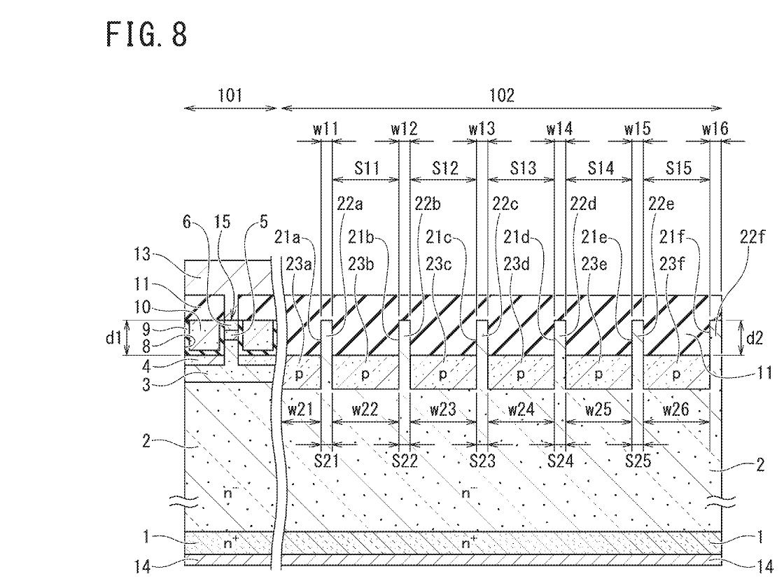

An insulated gate semiconductor device according to a third embodiment differs from the insulated gate semiconductor device according to the first embodiment illustrated in FIG. 6 in that the widths w11 to w16 of the terminal-side fin parts 22a to 22f in the edge termination part 102 are uniform, as illustrated in FIG. 8.

The gaps s11 to s15 between the terminal-side fin parts 22a to 22f may be uniform, for example. The widths w21 to w26 of the guard ring layers 23a to 23f may be uniform. The gaps s21 to s25 between the guard ring layers 23a to 23g may also be uniform. The other configurations of the insulated gate semiconductor device according to the third embodiment are substantially the same as those of the insulated gate semiconductor device according to the first embodiment, and overlapping explanations are not repeated below.

The configuration of the insulated gate semiconductor device according to the third embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment.

### FOURTH EMBODIMENT

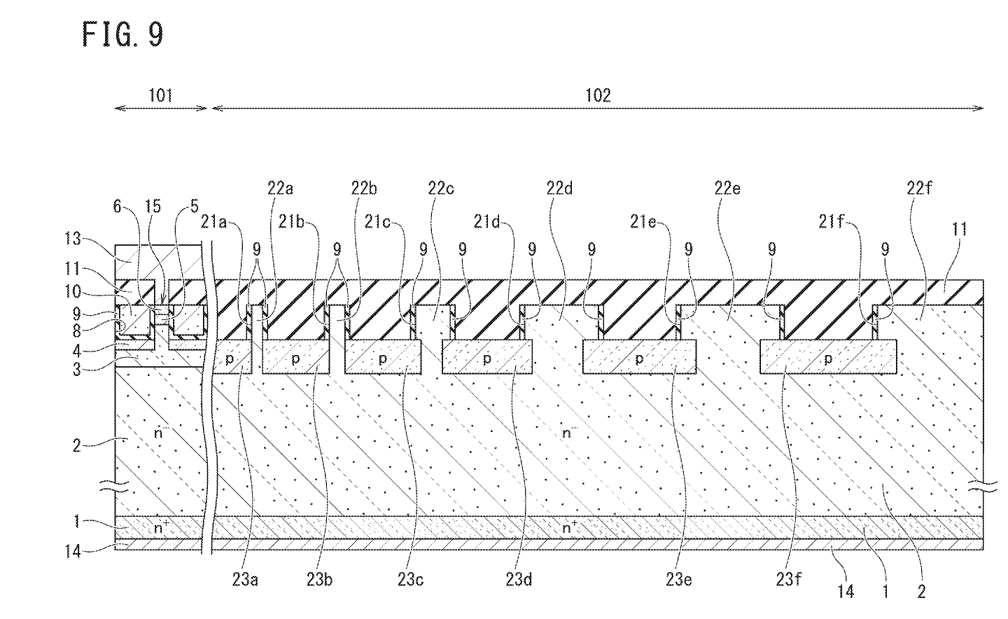

An insulated gate semiconductor device according to a fourth embodiment differs from the insulated gate semiconductor device according to the first embodiment illustrated in FIG. 6 in that the gate insulating film 9 is provided along the respective side surfaces of the terminal-side trenches 21a to 21f in the edge termination part 102, as illustrated in FIG. 9. The gate insulating film 9 is not provided on the respective bottom surfaces of the terminal-side trenches 21a to 21f but only provided along the respective side surfaces. The respective side surfaces of the terminal-side fin parts 22a to 22f are in contact with the gate insulating film 9. The gate insulating film 9 in the edge termination part 102 can be formed simultaneously with the gate insulating film 9 in the active part 101.

While FIG. 9 illustrates the case in which the gate insulating film 9 is provided along the side surfaces of all of the terminal-side trenches 21a to 21f, the gate insulating film 9 may be provided on the side surfaces of some of the terminal-side trenches 21a to 21f located on the inner side (for example, the terminal-side trenches 21a and 21b). The other configurations of the insulated gate semiconductor device according to the fourth embodiment are substantially the same as those of the insulated gate semiconductor device according to the first embodiment, and overlapping explanations are not repeated below.

The configuration of the insulated gate semiconductor device according to the fourth embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment. Further, the provision of the gate insulating film 9 on the side surfaces of the terminal-side trenches 21a to 21f can avoid pattern collapse of the terminal-side fin parts 22a to 22f.

### FIFTH EMBODIMENT

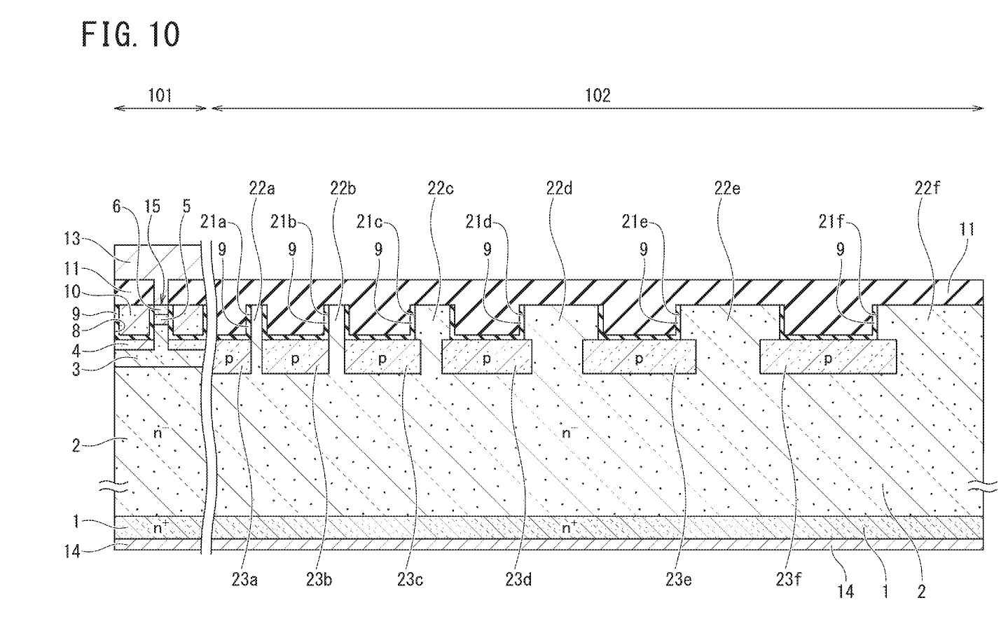

An insulated gate semiconductor device according to a fifth embodiment differs from the insulated gate semiconductor device according to the first embodiment illustrated in FIG. 6 in that the gate insulating film 9 is provided along the side and bottom surfaces of the respective terminal-side trenches 21a to 21f in the edge termination part 102, as illustrated in FIG. 10. The gate insulating film 9 in the edge termination part 102 can be formed simultaneously with the gate insulating film 9 in the active part 101. The respective side surfaces of the terminal-side fin parts 22a to 22f are in contact with the gate insulating film 9.

While FIG. 10 illustrates the case in which the gate insulating film 9 is provided along the side and bottom surfaces of all of the terminal-side trenches 21a to 21f, the gate insulating film 9 may be provided on the side and bottom surfaces of some of the terminal-side trenches 21a to 21f located on the inner side (for example, terminal-side trenches 21a and 21b). The other configurations of the insulated gate semiconductor device according to the fifth embodiment are substantially the same as those of the insulated gate semiconductor device according to the first embodiment, and overlapping explanations are not repeated below.

The configuration of the insulated gate semiconductor device according to the fifth embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment. Further, the provision of the gate insulating film 9 on the side and bottom surfaces of the terminal-side trenches 21a to 21f can avoid pattern collapse of the terminal-side fin parts 22a to 22f.

### SIXTH EMBODIMENT

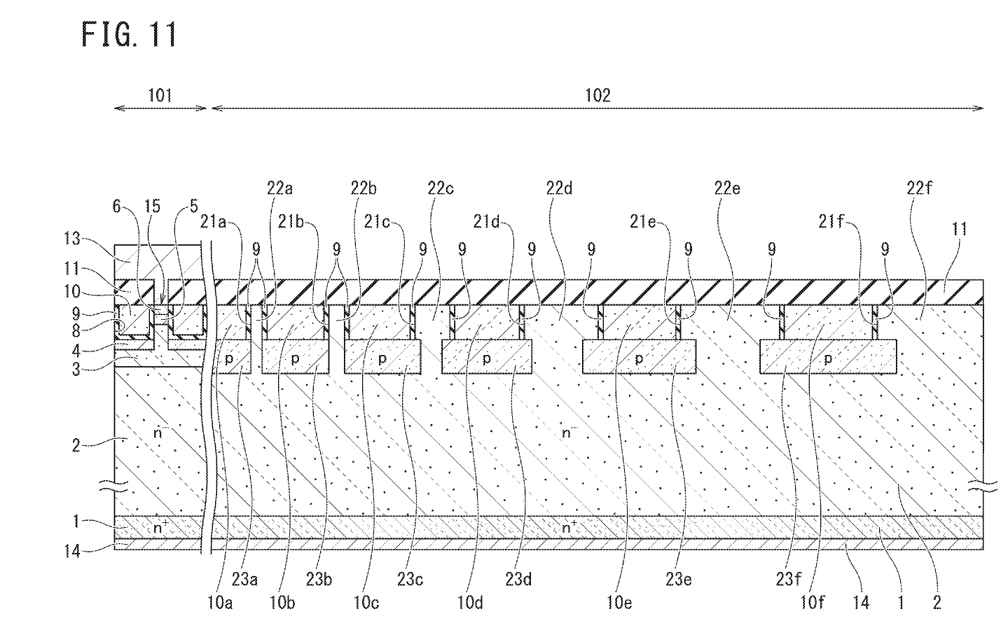

An insulated gate semiconductor device according to a sixth embodiment differs from the insulated gate semiconductor device according to the first embodiment illustrated in FIG. 6 in that the gate insulating film 9 and polysilicon layers 10a to 10f are buried inside the respective terminal-side trenches 21a to 21f in the edge termination part 102, as illustrated in FIG. 11.

The gate insulating film 9 is not provided on the bottom surfaces of the respective terminal-side trenches 21a to 21f but only provided along the respective side surfaces. The respective side surfaces of the polysilicon layers 10a to 10f are in contact with the gate insulating film 9. The bottom surfaces of the polysilicon layers 10a to 10f are in contact with the top surfaces of the guard ring layers 23a to 23f. The polysilicon layers 10a to 10f include the same material as the gate electrode 10 in the active part 101. The polysilicon layers 10a to 10f have substantially the same impurity concentration as the gate electrode 10 in the active part 101. The polysilicon layers 10a to 10f can be formed simultaneously with the gate electrode 10 in the active part 101 in the same process.

While FIG. 11 illustrates the case in which the gate insulating film 9 and the polysilicon layers 10a to 10f are buried inside all of the terminal-side trenches 21a to 21f, the gate insulating film 9 and the polysilicon layers 10a to 10f may be provided inside some of the terminal-side trenches 21a to 21f located on the inner side (for example, the terminal-side trenches 21a and 21b). The other configurations of the insulated gate semiconductor device according to the sixth embodiment are substantially the same as those of the insulated gate semiconductor device according to the first embodiment, and overlapping explanations are not repeated below.

The configuration of the insulated gate semiconductor device according to the sixth embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment. Further, by burying the gate insulating film 9 and the polysilicon layers 10a to 10f inside the terminal-side trenches 21a to 21f, pattern collapse of the terminal-side fin parts 22a to 22f can be avoided.

### SEVENTH EMBODIMENT

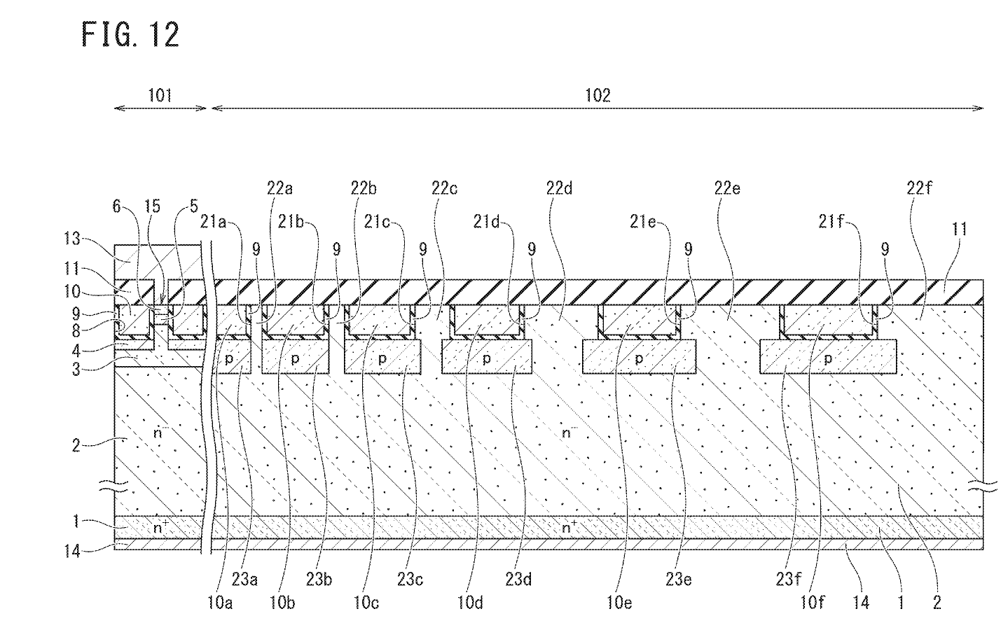

An insulated gate semiconductor device according to a seventh embodiment differs from the insulated gate semiconductor device according to the first embodiment illustrated in FIG. 6 in that the gate insulating film 9 and the polysilicon layers 10a to 10f are buried inside the respective terminal-side trenches 21a to 21f in the edge termination part 102, as illustrated in FIG. 12.

The gate insulating film 9 is provided along the side and bottom surfaces of the respective terminal-side trenches 21a to 21f. The polysilicon layers 10a to 10f are buried inside the respective terminal-side trenches 21a to 21f with the gate insulating film 9 interposed. The polysilicon layers 10a to 10f include the same material as the gate electrode 10 in the active part 101. The polysilicon layers 10a to 10f have substantially the same impurity concentration as the gate electrode 10 in the active part 101. The polysilicon layers 10a to 10f can be formed simultaneously with the gate electrode 10 in the active part 101 in the same process.

While FIG. 12 illustrates the case in which the gate insulating film 9 and the polysilicon layers 10a to 10f are buried inside all of the terminal-side trenches 21a to 21f, the gate insulating film 9 and the polysilicon layers 10a to 10f may be provided inside some of the terminal-side trenches 21a to 21f located on the inner side (for example, the terminal-side trenches 21a and 21b). The other configurations of the insulated gate semiconductor device according to the seventh embodiment are substantially the same as those of the insulated gate semiconductor device according to the first embodiment, and overlapping explanations are not repeated below.

The configuration of the insulated gate semiconductor device according to the seventh embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment. Further, by burying the gate insulating film 9 and the polysilicon layers 10a to 10f inside the terminal-side trenches 21a to 21f, pattern collapse of the terminal-side fin parts 22a to 22f can be avoided.

### EIGHTH EMBODIMENT

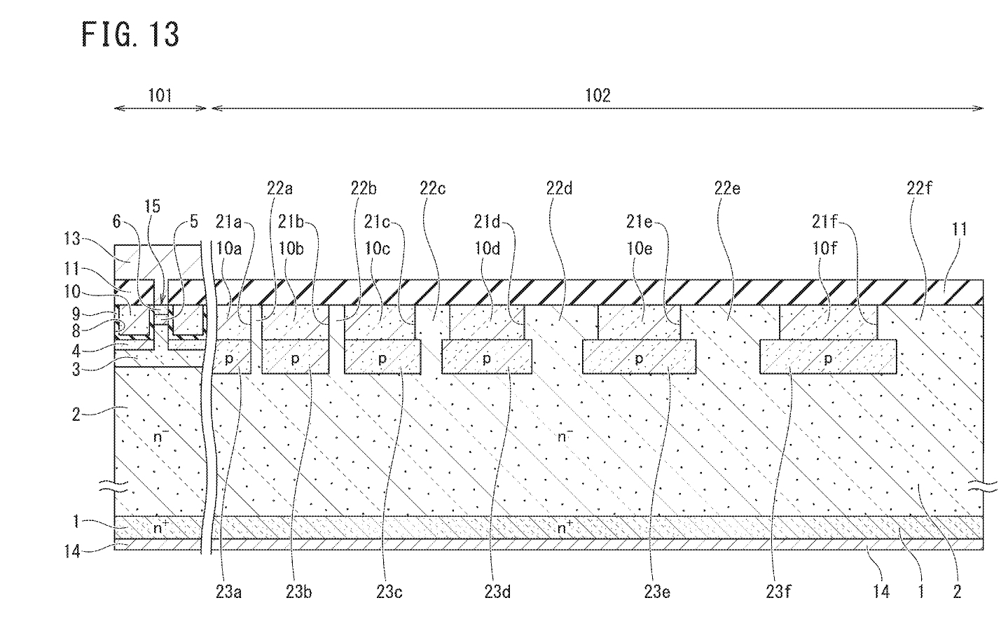

An insulated gate semiconductor device according to an eighth embodiment differs from the insulated gate semiconductor device according to the first embodiment illustrated in FIG. 6 in that the polysilicon layers 10a to 10f are buried inside the terminal-side trenches 21a to 21f in the edge termination part 102, as illustrated in FIG. 13. The side surfaces of the polysilicon layers 10a to 10f are in contact with the side surfaces of the terminal-side fin parts 22a to 22f.

The bottom surfaces of the polysilicon layers 10a to 10f are in contact with the top surfaces of the guard ring layer 23a to 23f. The polysilicon layers 10a to 10f include the same material as the gate electrode 10 in the active part 101. The polysilicon layers 10a to 10f have substantially the same impurity concentration as the gate electrode 10 in the active part 101. The polysilicon layers 10a to 10f can be formed simultaneously with the gate electrode 10 in the active part 101 in the same process.

While FIG. 13 illustrates the case in which the polysilicon layers 10a to 10f are buried inside all of the terminal-side trenches 21a to 21f, the polysilicon layers 10a to 10f may be provided inside some of the terminal-side trenches 21a to 21f located on the inner side (for example, the terminal-side trenches 21a and 21b). The other configurations of the insulated gate semiconductor device according to the eighth embodiment are substantially the same as those of the insulated gate semiconductor device according to the first embodiment, and overlapping explanations are not repeated below.

The configuration of the insulated gate semiconductor device according to the eighth embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment. Further, by burying the polysilicon layers 10a to 10f inside the terminal-side trenches 21a to 21f, pattern collapse of the terminal-side fin parts 22a to 22f can be avoided.

### NINTH EMBODIMENT

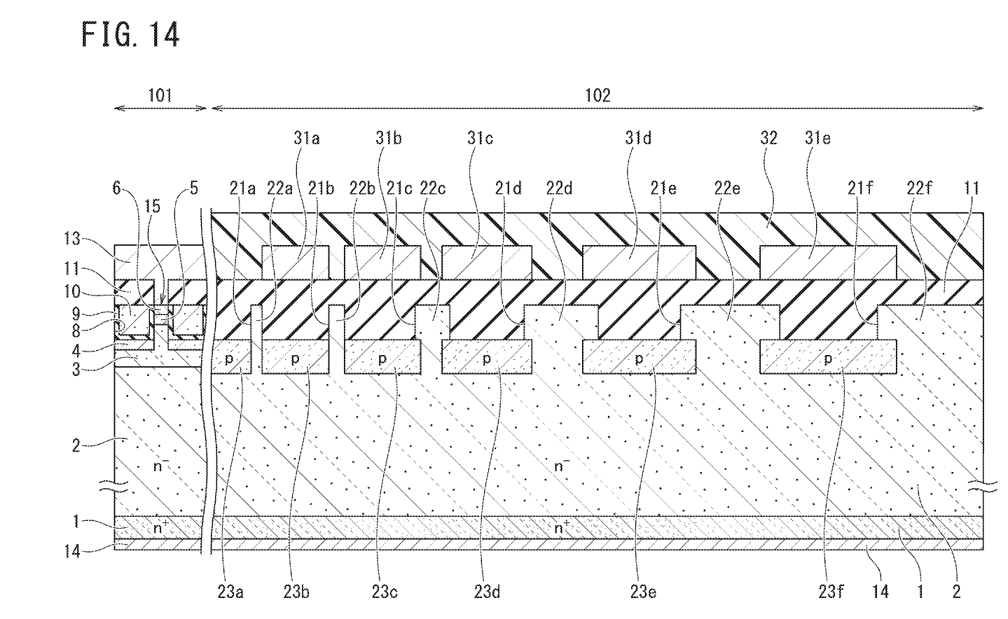

An insulated gate semiconductor device according to a ninth embodiment differs from the insulated gate semiconductor device according to the first embodiment illustrated in FIG. 6 in that a plurality of field plates 31a to 31e are provided on the top surface side of the insulating film 11 in the edge termination part 102, as illustrated in FIG. 14. The field plates 31a to 31e have a loop-shaped (frame-shaped) planar pattern surrounding the circumference of the active part 101. The field plates 31a to 31e are arranged separately from each other in a concentric state.

The field plates 31a to 31e include metal such as aluminum (Al) and copper (Cu), or include an alloy such as aluminum-silicon (Al-Si) and Al-Cu, for example. The field plates 31a to 31e may include the same material as the source electrode 13, and can be formed simultaneously with the source electrode 13. The field plates 31a to 31e are covered with a passivation film 32 including polyimide and the like. The other configurations of the insulated gate semiconductor device according to the ninth embodiment are substantially the same as those of the insulated gate semiconductor device according to the first embodiment, and overlapping explanations are not repeated below.

The configuration of the insulated gate semiconductor device according to the ninth embodiment, which includes the terminal-side fin parts 22a to 22f on the top surface side of the drift layer 2 in the edge termination part 102, can relax the electric field so as to improve the breakdown voltage, as in the case of the insulated gate semiconductor device according to the first embodiment. Further, the provision of the plural field plates 31a to 31e on the top surface side of the insulating film 11 can further enhance the relaxation of the electric field.

### OTHER EMBODIMENTS

As described above, the precent disclosure has been described according to the first to ninth embodiments, but it should not be understood that the description and drawings implementing a portion of this disclosure limit the precent disclosure. Various alternative embodiments, examples, and operational techniques will be apparent to those skilled in the art from this disclosure.

For example, the first to ninth embodiments each illustrate the case of using the vertical trench-gate MOSFET as the active element in the active part 101, but the respective embodiments may be applied to a case of using an insulated gate bipolar transistor (IGBT) including a p⁺-type collector region, instead of the n⁺-type drain region 1 in the MOSFET. Further, the respective embodiments may also be applied to a case of using a reverse conductive IGBT (RC-IGBT) or a reverse blocking IGBT (RB-IGBT), instead of a single IGBT.

Further, the first to ninth embodiments each illustrate the case in which the semiconductor chip 100 includes silicon carbide (SiC), but are not limited to this case. For example, the semiconductor chip 100 may include silicon (Si), or may include semiconductor (wide bandgap semiconductor) having a wider bandgap than Si, such as gallium nitride (GaN), gallium oxide (Ga₂O₃), diamond (C), and aluminum nitride (AlN).

In addition, the respective configurations disclosed in the first to ninth embodiments can be combined together as appropriate without contradiction with each other. As described above, the present disclosure includes various embodiments and the like not described herein. Therefore, the scope of the present disclosure is defined only by the subject matters recited in claims.

What is claimed is:

1. An insulated gate semiconductor device comprising:
a drift layer of a first conductivity-type provided along an active part including an active element and an edge termination part surrounding a circumference of the active part; and
a plurality of fin parts of the first conductivity-type provided separately from each other on a top surface side of the drift layer in the edge termination part so as to surround the circumference of the active part.

2. The insulated gate semiconductor device of claim 1, wherein
the active element includes:
a base region of a second conductivity-type provided on the top surface side of the drift layer;
a main region of the first conductivity-type provided on a top surface side of the base region; and
a gate electrode buried, with a gate insulating film interposed, in a pair of first trenches interposing side surfaces of the base region and the main region, and
an inversion layer is formed in a region separated from an interface between the base region and the gate insulating film.

3. The insulated gate semiconductor device of claim 2, wherein a width of the base region is 0.2 micrometers or less.

4. The insulated gate semiconductor device of claim 1, wherein a width of the respective fin parts is gradually increased toward an outer side of the edge termination part.

5. The insulated gate semiconductor device of claim 1, wherein a width of the respective fin parts is uniform from an inner side to an outer side of the edge termination part.

6. The insulated gate semiconductor device of claim 1, wherein a width of the respective fin parts on an innermost side of the edge termination part is 0.2 micrometers or smaller.

7. The insulated gate semiconductor device of claim 2, wherein a second trench is provided between the fin parts adjacent to each other.

8. The insulated gate semiconductor device of claim 7, wherein a depth of the second trench is common to a depth of the first trenches.

9. The insulated gate semiconductor device of claim 7, further comprising a guard ring layer of the second conductivity-type provided on the top surface side of the drift layer immediately under the second trench.

10. The insulated gate semiconductor device of claim 9, wherein the guard ring layer is in contact with a bottom surface of the second trench.

11. The insulated gate semiconductor device of claim 9, wherein the guard ring layer is separated from a bottom surface of the second trench.

12. The insulated gate semiconductor device of claim 7, wherein the gate insulating film is provided on a side surface of the second trench.

13. The insulated gate semiconductor device of claim 12, wherein a polysilicon layer is provided on the side surface of the second trench with the gate insulating film interposed.

14. The insulated gate semiconductor device of claim 7, wherein a polysilicon layer is provided on a side surface of the second trench.

15. The insulated gate semiconductor device of claim 1, further comprising a field plate provided on a top surface side of the respective fin parts with an insulating film interposed.
